(19) United States
(12) Patent Application Publication
(10) Pub. No.: US 2020/0131626 A1
(43) Pub. Date: Apr. 30, 2020

(54) FILMS AND LAMINATES WITH HIGH OXYGEN BARRIER AND METHODS OF MAKING THE SAME

(71) Applicant: Fres-co System USA, Inc., Telford, PA (US)

(72) Inventor: Jeffrey Scott Beer, Coopersburg, PA (US)

(21) Appl. No.: 16/665,489

(22) Filed: Oct. 28, 2019

Related U.S. Application Data
(60) Provisional application No. 62/752,594, filed on Oct. 30, 2018.

(51) Int. Cl. C23C 14/58; C23C 14/20; C23C 14/24; B65D 65/40; B65D 65/42

(52) U.S. Cl. CPC C23C 14/5853; C23C 14/20; B65D 65/42; B65D 65/40; C23C 14/24

(57) ABSTRACT

Disclosed is a laminated film for use to form a flexible package for holding an oxygen sensitive product and methods of making the film. The film includes a metalizable polymer film or cellulose film with aluminum vacuum deposited thereon. An acidic layer of polyvinyl alcohol and a polymer is coated on aluminum to cause a portion of the aluminum to be converted into an inorganic aluminum compound, whereupon said laminated film has a higher oxygen barrier value than the sum of the oxygen barrier values of its individual components Also disclosed are methods for making the laminated film.

### CROSS-REFERENCE OF RELATED APPLICATIONS

This utility application claims the benefit under 35 U.S.C. § 119(e) of Provisional Application Ser. No. 62/752,594 filed on Oct. 30, 2018 entitled Films and Laminates with High Oxygen Barrier and Methods of Making the Same. The entire disclosure of this provisional application is incorporated by reference herein.

### BACKGROUND OF THE INVENTION

### Field of Invention

This invention relates generally to films for flexible packaging and more particularly to films for packaging oxygen sensitive products and methods of making such films.

### Description of Related Art

Flexible packages formed of sheet materials have been used for many years and have wide acceptance for holding various products, e.g., roasted coffee and other foodstuffs. Prior art flexible, air-tight packages are commonly constructed of some plastic film, metal foil, or combinations thereof, in one or more plies and sealed along one or more seams. Such packages may be vacuumized after filling, but prior to sealing, so that the contents of the package are not exposed to the degradation effects of air.

Oxygen barrier films are available in the prior art from various sources. For example, 12-micron Mylar® LBT, available from DuPont Teijin Films, is a standard oriented polyester film having oxygen permeability is 9.0 cc/100 si/day. MYLAR® MC2, available from DuPont Teijin Films, is a polyester film vacuum coated with aluminum on one side and over-coated on both sides with Polyvinylidene chloride (PVDC) copolymer. The oxygen barrier of this material is typically 0.01 cc/100 si/day and is obtained by the simple combination of 12-micron polyester film, aluminum metallization, and two coating layers of PVDC copolymer. SARAFIL HMTCP, available from Polyplex Group, is a 12-micron polyester film vacuum coated with aluminum on one side using a higher amount of aluminum than is typically used in packaging films in order to obtain a higher barrier to oxygen. The aluminum deposition is measured using a light transmission densitometer, yielding an aluminum deposition of 2.7 OD. Oxygen barrier of this material is typically 0.05 cc/100 si/day. CEL-MET®, available from Celplast Limited, is a 12-micron polyester film vacuum coated with aluminum to yield the typical level of metallization for flexible packaging of 2.0 OD. The oxygen barrier of this material is typically 0.07 cc/100 si/day. NanoPack™ NanoSeal™ PET Barrier Coated Film, available from NanoPack, Inc., is a 12-micron polyester film solution coated with a polyvinyl alcohol-based oxygen barrier coating, like SunBar® Aeroblock coating available from Sun Chemical Corporation. The oxygen barrier of NanoPack™ NanoSeal™ PET Barrier Coated Film material is typically 0.1 to 0.3 cc/100 si/day. U.S. Pat. No. 8,080,297 (Kravitz) discloses the composition of the barrier coating. Sun Chemical Corporation is the assignee of several U.S. Patents for oxygen barrier coatings, such as: U.S. Pat. No. 8,268,108 (Illsley et al.); U.S. Pat. No. 9,221,956 (Illsley et al.); U.S. Pat. No. 9,573,344 (Illsley et al.); U.S. Pat. No. 9,598,599 (Illsley et al.); U.S. Pat. No. 9,624,380 (White et al.); U.S. Pat. No. 9,663,677 (Illsley et al.); and U.S. Pat. No. 9,982,148 (Illsley et al.). As is known, each layer of a laminated oxygen barrier film at its given thickness has an oxygen barrier value that can be determined experimentally. The composite oxygen barrier value of the laminated film is calculated using the following formula:

Pcomposite=1/((1/P₁)+(1/P₂)+(1/P₃))

where P is the barrier value of the particular layer. The above formula is for a three layer film. If the film only has two layers its composite value will be calculated by the formula: Pcomposite=1/((1/P₁)+(1/P₂)). So too, if the film has four layers its composite value will be calculated by the formula: Pcomposite=1/((1/P₁)+(1/P₂)+(1/P₃)+(1/P₄)).

In short, prior art laminated oxygen barrier films are designed to provide oxygen barrier through the simple additive effect of single barrier material layers being stacked one upon the other. There is no reactive or synergistic effect to achieve a higher barrier value.

Thus, a need exists for a laminated film exhibiting a higher oxygen barrier value than the sum of the barrier values of its various component layers. The subject invention addresses that need.

### SUMMARY OF THE INVENTION

One aspect of this invention is a laminated film for use to form a flexible package for holding an oxygen sensitive product. The film comprises a layer of a metalizable polymer film or cellophane film having a first surface, a layer of aluminum and an acidic layer. The layer of aluminum is vacuum deposited on the first surface. The layer of aluminum has a second surface. The acidic layer comprises polyvinyl alcohol (PVOH) and a polymer and is coated on the second surface to cause a portion of the aluminum layer contiguous with the second surface to be converted into an inorganic aluminum compound, whereupon the laminated film has a higher oxygen barrier value than the sum of the oxygen barrier values of its individual components.

In accordance with one preferred aspect of this invention the inorganic aluminum compound comprises aluminum oxide or an aluminum salt.

In accordance with another preferred aspect of this invention the layer of metalizable polymer film or cellophane film has a thickness in the range of approximately 0.00025 inches to 0.002 inches.

In accordance with another preferred aspect of this invention the thickness of the metalizable polymer film or cellophane film is approximately 0.00048 inches.

In accordance with another preferred aspect of this invention the layer of aluminum has a thickness in the range of approximately 10 Å (angstrom) to 50 Å (angstrom).

In accordance with another preferred aspect of this invention the thickness of the layer of aluminum is approximately 30 Å.

In accordance with another preferred aspect of this invention the acidic layer has a thickness in the range of approximately 0.000005 inches to 0.0002 inches.

In accordance with another preferred aspect of this invention the thickness of the acidic layer is approximately 0.0001 inches.

Another aspect of this invention is a method of making a laminated film having plural components. The laminated film is configured for use to form a flexible package for holding an oxygen sensitive product. The method comprises providing a first film comprising a polymer film or a cellophane film having an aluminum metalized layer thereon. The aluminum metalized layer has an exposed surface. An acidic coating of polyvinyl alcohol (PVOH) and a polymer is applied on the exposed surface to cause a portion of the aluminum layer contiguous with the exposed surface to be converted into an inorganic aluminum compound, whereupon the laminated film has a higher oxygen barrier value than the sum of the oxygen barrier values of its individual components.

In accordance with one preferred aspect of the method of this invention the inorganic aluminum compound comprises aluminum oxide or an aluminum salt.

In accordance with another preferred aspect of the method of this invention the first film is formed by providing a metalizable polymer film or a cellophane film and vacuum depositing aluminum on the metalizable polymer film or cellophane film.

In accordance with another preferred aspect of the method of this invention the method additionally comprises heating the acidic coating to remove any water therein. In accordance with another preferred aspect of the method of this invention the acidic coating is heated to approximately 180 degrees F.

In accordance with another preferred aspect of the method of this invention the polymer film or the cellophane film has a thickness in the range of approximately 0.00025 inches to 0.002 inches.

In accordance with another preferred aspect of the method of this invention the polymer film or the cellophane film has a thickness of approximately 0.00048 inches.

In accordance with another preferred aspect of the method of this invention the metalized aluminum layer has a thickness in the range of approximately 10 Å to 50 Å.

In accordance with another preferred aspect of the method of this invention the metalized aluminum layer has a thickness of approximately 30 Å.

In accordance with another preferred aspect of the method of this invention the acidic layer has a thickness in the range of approximately 0.000005 inches to 0.0002 inches.

In accordance with another preferred aspect of the method of this invention the acidic layer has a thickness of approximately 0.0001 inches.

### DESCRIPTION OF THE DRAWING

The invention will be described in conjunction with the following drawings in which like reference numerals designate like elements and wherein:

FIG. 1 is a block diagram flow chart showing two exemplary methods of this invention for making oxygen barrier films constructed in accordance with this invention;

FIG. 2 is a cross-section view, highly enlarged, but not to scale, of showing one step in the formation of an oxygen barrier film for flexible packages constructed in accordance with one aspect of this invention and made by the methods shown in FIG. 1; and

FIG. 3 is a more highly enlarged, cross section view of the portion of the oxygen barrier film shown within the broken circle designated by the reference number 3 in FIG. 2, wherein the film is shown the completion of its formation.

### DETAILED DESCRIPTION OF THE PREFERRED EMBODIMENT

Referring now to the various figures of the drawing wherein like reference characters refer to like parts, there is shown in FIG. 3 one exemplary embodiment of a laminated oxygen barrier film 20 which can be fabricated into a flexible package for holding an oxygen sensitive product, e.g., roasted coffee, to preserve that product by blocking atmospheric oxygen transmission. The film 20 includes plural component layers, each of which has its own oxygen barrier value to oxygen, which when combined produce a laminate whose composite barrier value to oxygen is higher than the sum of the individual component layers. The film 20 can be in the form of a sheet or web from which a package, e.g., a bag, can be fabricated, filled and sealed so that the contents of the bag are isolated from the oxygen in the ambient atmosphere.

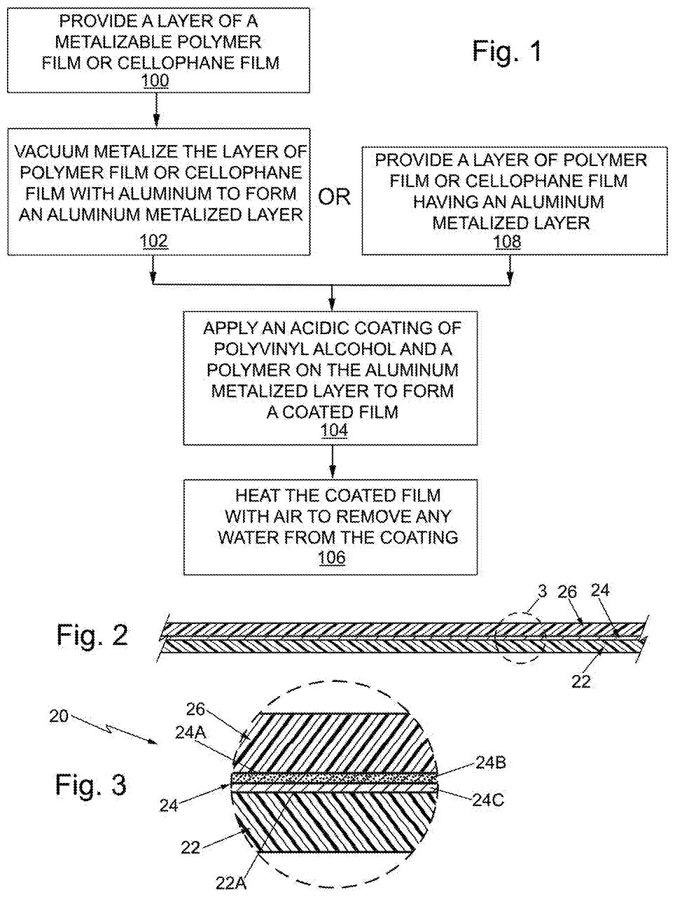

In the exemplary embodiment the film 20 is a laminate or composite of three layers 22, 24 and 26. The layers are formed and assembled into the laminated film 20 in accordance with method aspects of this invention shown in FIG. 1. Two exemplary methods of this invention are shown in FIG. 1.

Thus, as can be seen by the left side portion of FIG. 1 one method basically comprises providing a first film layer 22. The film layer 22 can be any metalizable polymer, e.g., polyester, polypropylene, nylon, EVOH, etc., or cellophane film. The metalizable film layer 22 has a surface 22A which is vacuum metallized with aluminum to form a metalized aluminum layer 24 on the surface 22A of the layer 22 as shown by block 102. As is known vacuum metallizing is a process where a metal, e.g., aluminum, is melted in a vacuum causing the metal to vaporize and deposit on a receptive surface. In this case, the aluminum forms a very thin layer 24 (e.g., in the range of 10 Å to 50 Å, and most preferably 30 Å) on the film 22, measured at 2.0 OD using a light transmission densitometer.

An acidic coating of formed of polyvinyl alcohol (PVOH) and a polymer which are coated on another polymer, e.g., polyethylene terephthalate (PET), is then coated as a layer 26 onto the exposed surface 24A of aluminum layer 24 as shown by block 104 and

FIG. 3. One exemplary acidic coating 26 is available from Sun Chemical Corporation under the trademark SunBar® Aeroblock WR PET. Other acidic coatings containing PVOH and at least one cross-linkable polymer may be used in place of the SunBar® Aeroblock WR PET. The exemplary layer 26 has a thickness is in the range of 0.00005 inches to 0.0002 inches, and most preferably 0.0001 inches. As shown by block 106, the resulting film 20 may be heated, e.g., heated to approximately 180° F. with hot air, to remove any water from PVOH in the layer 26.

The application of the layer 26 onto the metalized aluminum layer 24 causes the portion 24A (FIG. 3) of the aluminum layer 24 contiguous with the layer 26 to be converted into an optically clear, inorganic, aluminum compound, believed to be either aluminum oxide or an aluminum salt. The underlying portion of the aluminum layer 24, designated by the reference number 24C, remains as metallic aluminum.

An alternative method of making the film 20 is shown by right side portion of FIG. 1. That method entails providing a layer of polymer film or cellophane film that has already been metalized with a layer of aluminum as shown in block 108. One particularly suitable film is a polyester film with an aluminum metalized layer, is 12-micron CEL-MET®, like that identified above. That material is a composite of 12-micron polyester and a vacuum metallized layer of aluminum with a 2.0 optical density.

From that point onward the alternative method is the same as that described immediately above. In particular, the acidic coating layer 26 is applied onto the exposed surface 24A of the aluminum layer 24 to form the coated film 20 as shown by block 104 and, if desired, the coated film is then heated with hot air to remove any water from the PVOH coating as shown by block 106.

The resulting laminated oxygen barrier film 20 has an actual oxygen transmission rate (OTR) substantially lower than the sum of the calculated transmission rate of each of its layers. This is due to a chemical reaction between the acidic coating 26 and the aluminum 24 forming a new layer with high oxygen barrier. In particular, it is believed that that application of SunBar Aerobloc WR PET to the aluminum metallized side of 12 micron metallized PET creates a reaction between the aluminum and coating to result in an aluminum compound, e.g., aluminum oxide or an aluminum salt, which greatly increases barrier to oxygen as compared to the logically calculated value. In the example above, the oxygen barrier has been calculated to be 0.0457 cc/100 si/day for coated metallized polyester, which is at least a factor of 10 times a typical oxygen barrier of 0.001 to 0.002 cc/100 si/day.

Experimentation on the material revealed the chemical conversion of a portion of the layer of aluminum to an optically clear layer of a new material. Fourier-transform infrared spectroscopy (FTIR) analysis of this new clear layer indicates it is inorganic and therefore the result of an unexpected reaction between the aluminum and the coating.

This discovery has greatly enhanced the oxygen barrier of the subject invention beyond what was expected and therefore allows a higher level of oxygen protection than competitive materials.

The following formula is used to calculate the oxygen barrier contribution of the aluminum.

1/((1/P_{CEL-MET})−(1/P_{LBT}))=P2.0 OD ALUMINUM

1/(1/0.07)−(1/9)=0.0705=P2.0 OD ALUMINUM

Sun Chemical states “SunBar Aerobloc WR PET OTR will depend on the smoothness and the thickness of the film being coated as well as the uniformity and coat weight applied. Typical values tested according to ASTM F1927; Relative humidity (RH) 50% permeant (oxygen), 50% carrier (nitrogen), 23° C. on PET film: OTR <0.13 cc/100 in²-day (2.0 cc/m²-day). RH 75% permeant (oxygen), 75% carrier (nitrogen), 23° C.: PET film; OTR <0.65 cc/100 in²-day (10.0 cc/m²-day).”

Based on the above statement and using the lowest barrier value of 0.13 cc/100 si/day, the barrier value of the coating can be calculated. This is assuming 12-micron polyester film was coated. While Sun Chemical does not make this statement, it is believed to be accurate because SunBar Aerobloc WR PET is specifically designed for coating polyester film and that 12-micron polyester film is the most common thickness used in the packaging industry.

1/((1/P_{PET W/SUNBAR})−(1/P_{LBT}))=P_{SUNBAR}

1/(1/0.13)−(1/9)=0.1319=P_{SUNBAR}

The oxygen barrier of 2.0 OD metallized 12-micron polyester coated with Sunbar can be calculated using the following formula.

Pcomposite=1/((1/P₁)+(1/P₂)+(1/P₃))

Psunbar+12μ met PET=1/((1/9)+(1/0.0705)+(1/0.1319))=0.0457 cc/100 si/day

While the invention has been described in detail and with reference to specific examples thereof, it will be apparent to one skilled in the art that various changes and modifications can be made therein without departing from the spirit and scope thereof.

I claim:

1. A laminated film for use to form a flexible package for holding an oxygen sensitive product, said film comprising:
a layer of a metalizable polymer film or cellophane film having a first surface;
a layer of aluminum vacuum deposited on said first surface, said layer of aluminum having a second surface; and
an acidic layer of polyvinyl alcohol (PVOH) and a polymer coated on said second surface to cause a portion of said aluminum layer contiguous with said second surface to be converted into an inorganic aluminum compound, whereupon said laminated film has a higher oxygen barrier value than the sum of the oxygen barrier values of its individual components.

2. The laminated film of claim 1, wherein said inorganic aluminum compound comprises aluminum oxide or an aluminum salt.

3. The laminated film of claim 1, wherein said layer of metalizable polymer film or cellophane film has a thickness in the range of approximately 0.00025 inches to 0.002 inches.

4. The laminated film of claim 3, wherein said thickness is approximately 0.00048 inches.

5. The laminated film of claim 1, wherein said layer of aluminum has a thickness in the range of approximately 10 Å to 50 Å.

6. The laminated film of claim 5, wherein said thickness is approximately 30 Å.

7. The laminated film of claim 1, wherein said acidic layer has a thickness in the range of approximately 0.00005 inches to 0.0002 inches.

8. The laminated film of claim 7, wherein said thickness is approximately 0.0001 inches.

9. The laminated film of claim 3, wherein said layer of aluminum has a thickness in the range of approximately 10 Å to 50 Å, and wherein said acidic layer has a thickness in the range of approximately 0.00005 inches to 0.0002 inches.

10. The laminated film of claim 9, wherein said thickness of said layer of polymer film or cellophane film is approximately 0.00048 inches, wherein said thickness of said aluminum is approximately 30 Å, and wherein said thickness of said acidic layer is approximately 0.0001 inches.

11. A method of making a laminated film having plural components, said laminated film being configured for use to form a flexible package for holding an oxygen sensitive product, said method comprising:
providing a first film comprising a polymer film or a cellophane film having an aluminum metalized layer thereon, said aluminum metalized layer having an exposed surface;
applying an acidic coating of polyvinyl alcohol (PVOH) and a polymer on said exposed surface to cause a portion of said aluminum layer contiguous with said exposed surface to be converted into an inorganic aluminum compound, whereupon said laminated film has a higher oxygen barrier value than the sum of the oxygen barrier values of its individual components.

12. The method of claim 11, wherein said inorganic aluminum compound comprises aluminum oxide or an aluminum salt.

13. The method of claim 11, wherein said first film is formed by providing a metalizable polymer film or a cellophane film and vacuum depositing aluminum on said metalizable polymer film or cellophane film.

14. The method of claim 11, additionally comprising heating said acidic coating to remove any water therein.

15. The method of claim 14, wherein said acidic coating is heated to approximately 180 degrees F.

16. The method of claim 11, wherein said polymer film or said cellophane film has a thickness in the range of approximately 0.00025 inches to 0.002 inches.

17. The method of claim 16, wherein said thickness is approximately 0.00048 inches.

18. The method of claim 11, wherein said metalized aluminum layer has a thickness in the range of approximately 10 Å to 50 Å.

19. The method of claim 18, wherein said thickness is approximately 30 Å.

20. The method of claim 11, wherein said acidic layer has a thickness in the range of approximately 0.00005 inches to 0.0002 inches.

21. The method of claim 20, wherein said thickness is approximately 0.0001 inches.

22. The method of claim 16, wherein said layer of aluminum has a thickness in the range of approximately 10 Å to 50 Å, and wherein said acidic layer has a thickness in the range of approximately 0.00005 inches to 0.0002 inches.

23. The method of claim 22, wherein said thickness of said layer of said polymer film or said cellophane film is approximately 0.00048 inches, wherein said thickness of said aluminum is approximately 30 Å, and wherein said thickness of said acidic layer is approximately 0.0001 inches.
